(19) United States
(12) Patent Application Publication
(10) Pub. No.: US 2012/0326710 A1
(43) Pub. Date: Dec. 27, 2012

(54) METHOD FOR DETECTING THE MECHANICAL STRESS TO WHICH A PART MADE OF A MAGNETOSTRICTIVE MATERIAL IS SUBJECTED

(75) Inventors: Laure-Line Rouve, Theys (FR); Antoine Viana, Herbeys (FR)

(73) Assignee: INSTITUT POLYTECHNIQUE DE GRENOBLE, Grenoble Cedex 1 (FR)

(21) Appl. No.: 13/574,181

(22) PCT Filed: Jan. 21, 2011
(86) PCT No.: PCT/FR11/50122

§ 371 Date: Sep. 11, 2012

(30) Foreign Application Priority Data
Jan. 22, 2010 (FR) 10/50440
Jan. 21, 2011 (FR) PCT/FR2011/050122

(51) Int. Cl. G01R 33/18

(52) U.S. Cl. 324/209

(57) ABSTRACT

The invention relates to a method for detecting the stress to which a part of a magnetic material having a detectable magnetostriction, such as a ferromagnetic material, is submitted, comprising the steps of: a) applying a variable stress to the part b) measuring the magnetic field (B) in the vicinity of the part during the application of the variable stress to the part; and c) comparing the measurement with a reference measurement.

### TECHNICAL FIELD

The present disclosure relates to a method for detecting the mechanical stress to which a part made of a magnetic material having observable and detectable magnetostriction properties is submitted. More specifically, the present disclosure relates to methods enabling to know, ex post facto or in real time, the stress to which such a part is submitted.

### DISCUSSION OF THE ART

To determine whether a part has been submitted to siynificant stress during its use, a known method comprises analyzing the structure of this part by X-ray diffusion or by using ultrasounds. Such techniques enable to visualize fracture lines in the material. They however do not enable to determine the maximum stress to which the material has been submitted or to detect that the predefined maximum stress that the material can withstand has been exceeded.

U.S. Pat. No. 5,012,189 provides a method enabling to calculate the stress to which a magnetic material is being submitted. However, this method is difficult to implement. It implies measuring the anhysteretic curve of the unstressed material (reference curve) and that of the stressed material. The interval between the two curves enables to go back to the value of the stress to which the material is currently being submitted. An anhysteretic curve can be experimentally determined as follows: the operator sets an external field; by means of an alternating field generation system, it submits the material to an alternating magnetic field H having an amplitude decreasing from a high value to zero; when the alternating field has reached 0, the operator repeats this operation for a greater external field; by so performing for an external field varying from 0 to Hsat, Hsat being the saturation magnetic field, anhysteretic curve Banh is obtained. This operation is long, is performed under constant stress, and requires being able to submit the ferromagnetic material to an alternating external field, which implies that the material is accessible and that its shape and its position enable to install the system necessary to obtain the alternating field.

Thus, there is a need for a simple method enabling to follow in real time the variable stress to which a part made of a magnetostrictive material, for example, a ferromagnetic material, is submitted, or to determine ex post facto the maximum stress to which the part has been submitted during its history.

### SUMMARY

A simple embodiment of the present invention provides a simple method for detecting the stress to which a part having an observable and detectable magnetostriction is submitted.

An embodiment of the present invention further provides a simple method for determining ex post facto the value of the maximum stress to which a part of a magnetostrictive material has been submitted in the past.

An embodiment of the present invention further provides a simple method of real time detection of the fact that the stress to which a part made of a magnetostrictive material is submitted exceeds a reference value.

An embodiment of the present invention further provides a method enabling to count the number of mechanical cycles to which a part of a magnetostrictive material has been submitted.

Thus, an embodiment of the present invention provides a method for detecting the stress to which is submitted a part of a magnetic material having a detectable magnetostriction, such as a ferromagnetic material comprising the steps of:

(a) applying a variable stress to the part;

(b) measuring the magnetic field in the vicinity of the part during the application of the variable stress to the part; and

(c) comparing said measurement with a reference measurement.

According to an embodiment of the present invention, step (b) comprises measuring the curve of the magnetic field in the vicinity of the part according to an increasing stress which is applied thereto, up to a predetermined maximum stress.

According to an embodiment of the present invention, step (c) is a step of determination of the shape of said curve by comparing it with reference curves.

According to an embodiment of the present invention, the reference curves are exponential or linear curves.

According to an embodiment of the present invention, the part of a magnetic material is deemed to have been stressed, in the past, with a maximum stress greater than said predetermined maximum stress if said measured curve becomes close to a linear curve, is deemed not to have been stressed or to have had its magnetic past deleted by a magnetic processing if said measured curve becomes close to an exponential curve, and is deemed to have been stressed, in the past, with a maximum stress smaller than said predetermined maximum stress if the measured curve becomes close to a straight line, and then has a stronger slope to join an exponential curve.

According to an embodiment of the present invention, the stress corresponding to the transition between the straight line and the stronger slope of said measured curve corresponds to the maximum stress to which the part has been submitted in the past.

According to an embodiment of the present invention, the measurement of step (b) is performed under an external field different from the field under which the part has been stressed in the past.

According to an embodiment of the present invention, the method further comprises an initial step comprising applying a maximum initial stress to the part.

According to an embodiment of the present invention, the comparison at step (c) comprises determining whether the absolute value of the magnetic field in the vicinity of the part measured at step (b) exceeds a predetermined maximum magnetic field associated with said maximum initial stress.

According to an embodiment of the present invention, the method further comprises a step of transmission of an alert if the absolute value of the magnetic field in the vicinity of the part measured at step (b) exceeds said predetermined maximum magnetic field.

According to an embodiment of the present invention, the comparison at step (c) comprises determining whether the absolute value of the magnetic field in the vicinity of the part measured at step (b) varies around a predetermined value, to determine a number of mechanical cycles to which the part has been submitted.

According to an embodiment of the present invention, the comparison at step (c) is a comparison between the measured magnetic field and a curve determined by a prior characterization step associating magnetic field and stress.

According to an embodiment of the present invention, the measurement of the magnetic field in the vicinity of the part, for example, a demagnetization or a polarization, is obtained by means of a three-axis magnetometer.

According to an embodiment of the present invention, the method further comprises a preliminary step of magnetic processing of the part to delete its magnetic past.

### BRIEF DESCRIPTION OF THE DRAWINGS

The foregoing and other objects, features and advantages of the present invention will be discussed in detail in the following non-limiting description of specific embodiments in connection with the accompanying drawings, among which:

FIG. 1 illustrates a test device highlighting the principle implemented in the methods described herein;

FIGS. 2A to 2C are curves illustrating results obtained by means of the test device of FIG. 1;

FIG. 3 is a flowchart of a first method according to an embodiment of the present invention;

FIG. 4 is a flowchart of a second method according to an embodiment of the present invention; and

FIG. 5 is a timing diagram illustrating the method of FIG. 4.

### DETAILED DESCRIPTION

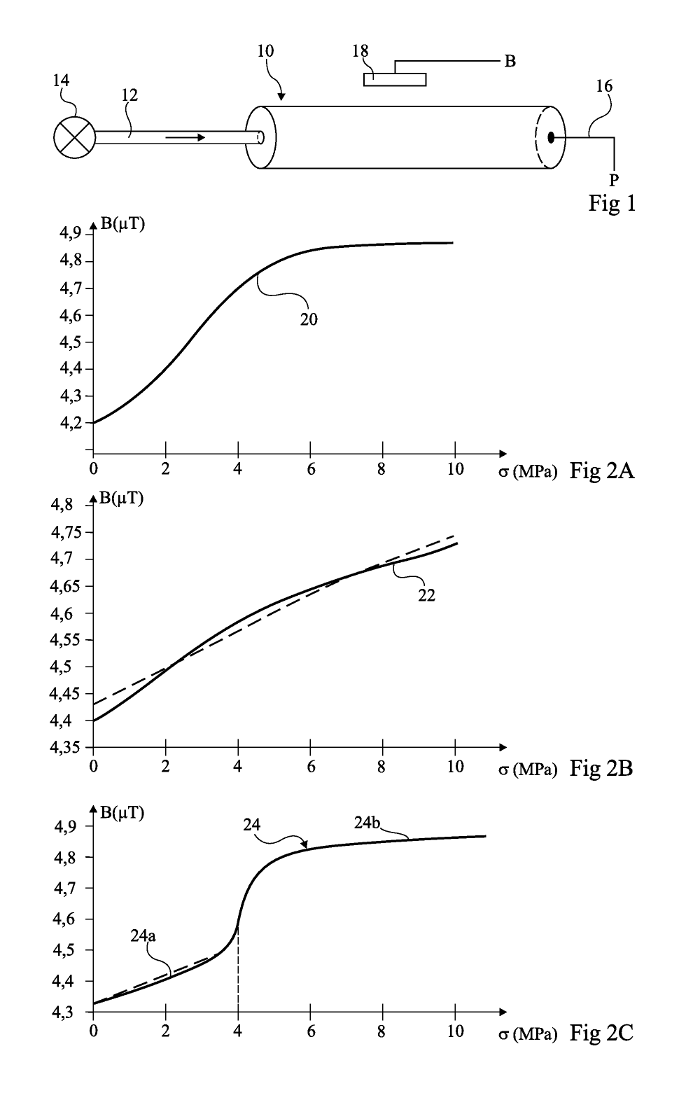

To detect the stress undergone by a part of a magnetic material having magnetostriction properties (magnetostrictive material), for example, of a ferromagnetic material, ex post facto or in real time, the inventors provide taking advantage of a relation that they have brought to light during experiments which will be described hereafter in relation with FIGS. 1 and 2A to 2C, between the magnetic field in the vicinity of the part (due to the magnetization thereof) and the stress applied to the part.

It should be noted that “magnetic material having magnetostriction properties” designates any magnetic material having such observable and detectable properties. This category thus includes all ferromagnetic materials, even those having low magnetostriction coefficients, especially Permalloy (alloy with 80% of nickel and 20% of iron). This material, having very low magnetostriction coefficients, should have little magnetostrictive effect. However, the anisotropy constants of this material are even lower than its magnetostriction coefficients, which implies that magnetostrictive effects still dominate for the material. This makes the magnetization of this material very sensitive to the smallest mechanical stress. It should however be noted that, to resist high stress, other magnetostrictive materials may be preferred to Permalloy.

FIG. 1 illustrates a test device comprising a duct 10 made of a magnetostrictive material, for example, made of steel, and closed at its two ends. A fluid in introduced into duct 10 by means of a pipe 12, the amount of fluid in duct 10 being adjusted by means of a gate 14. A pressure sensor 16 measures the pressure in duct 10. Pressure P in the duct corresponds to the stress applied thereto. A magnetic field sensor 18 is placed outside of the duct and enables to measure magnetic field B around it.

By means of the device of FIG. 1, different stress values may be applied to part 10 and curves of the magnetic field around the duct according to the stress applied thereto by the fluid may be plotted. The inventors have observed that the shape of the curve of the magnetic field according to the stress varies according to the past of the magnetic material, and more specifically according to the maximum mechanical stress to which the material has been submitted in the past.

FIGS. 2A to 2C are curves illustrating results obtained by means of the test device of FIG. 1 in several cases.

In a first case, duct 10 has been previously magnetically processed to delete its magnetic memory. For example, the duct has been demagnetized. Then, it has been submitted to no mechanical stress. In the example of the test device of FIG. 1, this means that no pressurized fluid has been introduced into duct 10 and has exerted no stress on the walls thereof since the moment when it has been magnetically processed.

FIG. 2A illustrates curve 20 of magnetic field B around the duct when it is applied an increasing stress σ. In the shown example, stress σ (differential pressure between the inside and the outside of the duct) increases from 0 to 10 MPa. The inventors have determined that, in this case, the obtained curve 20 follows a curve of exponential shape.

In a second case, duct 10 has been previously magnetically processed to delete its magnetic memory, for example, by being demagnetized, after which it has been applied a stress corresponding to a pressure higher than 10 MPa.

FIG. 2B illustrates curve 22, which is then obtained by applying an increasing stress on the part and by measuring the value of magnetic field B according to this stress σ. The inventors have determined that, in this case, the obtained curve, for a stress σ corresponding to a pressure varying between 0 and 10 MPa, is a linear curve.

In a third case, duct 10 has been previously magnetically processed to delete its magnetic memory, for example, by being demagnetized, after which it has been applied a stress corresponding to a pressure greater than 4 MPa.

FIG. 20 illustrates curve 24 obtained afterwards by applying an increasing stress to the part and by measuring magnetic field B according to the applied stress σ, stress a varying between 0 and 10 MPa. This curve is comprised of two portions. A first portion 24a, between σ=0 and approximately σ=4 MPa, is substantially linear. At approximately 4 MPa, the slope of curve 24 abruptly increases and joins an exponential curve (curve portion 24b).

Starting from these observations, the inventors provide various methods for monitoring the stress applied to a magnetostrictive part. One of these methods enables to determine ex post facto the value of the maximum stress to which the part has been previously submitted. Another method enables to monitor in real time the variable stress applied to such a part and to detect that a previously-determined threshold thereof has been exceeded. Another method enables to control the quality of parts at the factory gate. Another method enables to count mechanical cycles applied to a part. These various methods will be detailed hereinafter.

It should be noted that a magnetic processing such as a demagnetization of a part made of a magnetostrictive material cancels the effect and the visibility of the stress to which the part has previously been submitted. It should thus be clear that the initial demagnetization of the part provided in the methods described hereinafter should in practice only be performed on parts which have never been stressed, for example, at the factory gate.

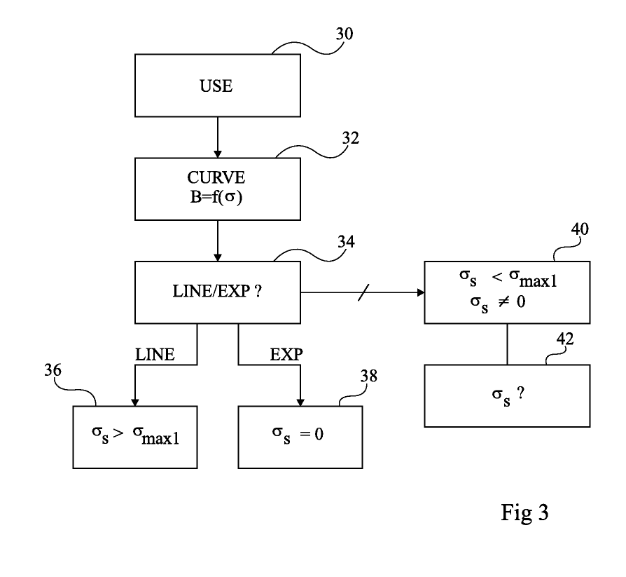

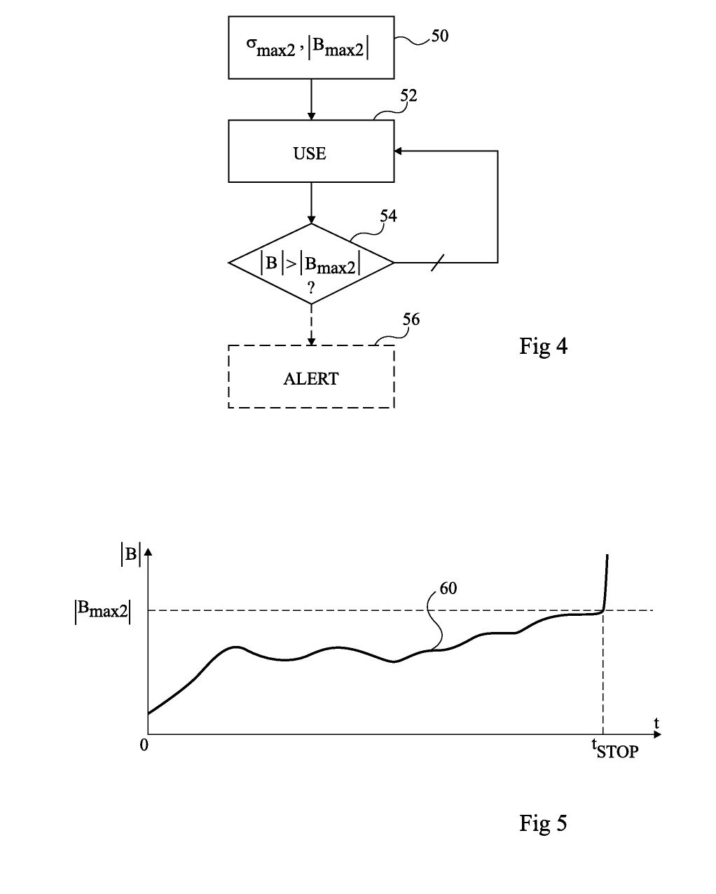

FIGS. 3 and 4 are flowcharts showing two of these methods.

A first provided method, illustrated in FIG. 3, enables, by taking advantage of an analysis of the different types of curves defined hereabove, to measure the maximum stress to which a magnetostrictive part has been submitted in the past. To achieve this, the part is initially magnetically processed to delete its magnetic memory, for example by being demagnetized, before being used in a step 30 (USE) during which it may be submitted to stress.

Then, at a step 32, the part is no longer in use and the curve of the magnetic field around the part is plotted according to an increasing stress σ which is applied thereto (CURVE B=f(σ)), from no stress to a maximum stress σₘₐₓ₁. As an example, stress σₘₐₓ₁ may be a predetermined stress that the part being used is not supposed to exceed. It should be noted that the measurement of this curve may be performed on the part in its operating environment. The part may also be extracted from its environment to plot this curve. Indeed, the inventors have observed that a change in environment, capable of generating a change of the external magnetic field, does not modify the general outlook of the curves of FIGS. 2A to 2C. In particular, the slope increase at the level of the maximum stress to which the part has been submitted in the past in the case of FIG. 2C is still visible.

The next steps are steps of comparison of the shape of the curve obtained at step 32 with shapes of reference curves corresponding to the curves of FIGS. 2A and 2B. In the shown example, a step 34 (LINE/EXP ?) comprises comparing the curve obtained at step 32 with linear or exponential curves.

In the case where the curve obtained at step 32 has a substantially linear shape (LINE), it is proceeded to a step 36 (σₛ>σₘₐₓ₁) in which it can be asserted that stress σₛ to which the part is submitted during use step 30 has exceeded value σₘₐₓ₁.

In the case where the curve obtained at step 32 has an exponential shape, it is proceeded to a step 38 (σₛ=0) in which it can be said that no stress has been applied to the part during use step 30 or that the part has seen its magnetic past deleted by a magnetic processing (a demayuetization, for example).

If the comparison of step 34 provides no result, that is, if the curve obtained at step 32 is neither linear, nor exponential, it can be concluded, at a step 40 (σiₛ<σₘₐₓ₁, σₛ≠0), that the part, during initial usage step 30, has been submitted to a stress having a value which has not exceeded value σₘₐₓ₁. The curve obtained at step 32 then is a curve such as the curve of FIG. 2C.

Then, an optional step 42 may be provided to determine the value of the maximum stress to which the part has been submitted in the past. To obtain this value, the time of occurrence of an abrupt change of slope of the curve (corresponding to the point located between portions 24a and 24b of the curve of FIG. 2C) is determined on the curve of the magnetic field around the part according to an increasing stress σ which is applied thereto.

It should be noted that the comparison of step 34 may be performed by using any adapted calculation means such as a computer, enabling a comparison with known curve shapes. As an example, such comparisons may be performed by an adjustment using the least error squares method or by any other curve shape approximation method. Those skilled in the art will easily elect the maximum standard deviation to be set between the curve originating from the measurement and the theoretical curve to which it becomes close, to obtain a good comparison.

Further, it should be noted that the steps disclosed herein are an example only. In particular, the shape of the curve obtained at step 32 may be determined in a single step of comparison of the obtained curve with curves such as the curves of FIGS. 2A to 2C, to obtain in automated fashion the curve shape and, possibly, the maximum value of stress σₛ to which the magnetostrictive part has been submitted.

The method described in relation with FIG. 3 thus enables to determine ex post facto the maximum stress applied to the magnetostrictive material part during the use thereof. It should be noted that if the part has been submitted to a stress greater than σₘₐₓ₁ (step 36), the determination may be completed by increasing applied stress σ beyond σₘₐₓ₁, to determine an approximate value of stress σₛ to which the part has been submitted. The value of stress σₛ will then substantially correspond to the point of strong slope variation of the curve after the linear area (curve such as that in FIG. 2C).

The method of FIG. 3 is particularly capable of determining whether the maximum stress applied to a part during the use thereof has not been greater than a maximum operating stress, for example calibrated at the factory gate.

The curve may be obtained at step 32 by placing a magnetometer, preferably of three-axis type, close to the part and by applying an increasing mechanical stress to the part, for example, a pressurization, or, in the case of a duct, by increasing the pressure in the duct by means of any adapted device. A three-axis magnetometer enables to measure the three spatial components of the magnetic field and allows a good detection of the shape of the curve obtained at step 32. Indeed, according to the placing of the sensor and to the shape of the object, the three components of the magnetic field may vary more or less according to the applied stress. A detection by means of a three-axis magnetometer enables to do away with the orientation of the magnetic field around the part.

FIG. 4 is a timing diagram of a second method according to an embodiment of the present invention where the stress to which the part is submitted is desired to be followed in real time, for example, to notify a user in case a reference value has been exceeded.

In an initial step 50, and after having processed the part to delete its magnetic memory, for example, by demagnetization, a stress σₘₐₓ₂ forming a reference stress that the part should not exceed in a subsequent use is applied to the part. To accurately and fixedly apply this stress, due to the creeping properties of the materials used, this stress σₘₐₓ₂ will preferably be applied by carrying out several stress cycles (application of a stress σₘₐₓ₂ followed by a release of the stress). At the same time, absolute value |Bₘₐₓ₂| of the magnetic field (or of one or several components of the magnetic field), around the part, corresponding to this stress σₘₐₓ₂, is determined. Preferably, σₘₐₓ₂ will be determined under the same field (if need be controlled by an external field generator or by coils) as that under which the measurement will be performed.

Then, the part is used during a step 52 (USE). During this use of the part, a system for measuring the magnetic field around it is provided to determine, at a step 54, whether absolute value |B| of this magnetic field exceeds or not value |Bₘₐₓ₂|. In the case where |B|<|Bₘₐₓ₂|, the system may keep on operating (step 52). This then corresponds to a position on a curve such as that illustrated in FIG. 2C, in linear portion 24a.

In the case where |B|>|Bₘₐₓ₂|, the fact that the maximum stress to be applied to the part has been exceeded is detected. This is linked to the change of slope of field ⊕B| when pre-stress σₘₐₓ₂ has been reached (transition between portions 24a and 24b in the curve of FIG. 2C). It can then be provided to send an alert signal (step 55, ALERT) or to stop the system.

The method of FIG. 4 enables to continuously monitor the stress applied to a part made of a magnetostrictive material. It may for example be applied to the monitoring of a duct where the pressure must not exceed a given threshold. Indeed, since it is not intrusive, this method is less complex to implement than an internal pressure-monitoring device. It should be noted that even if the duct to be monitored is not made of a magnetostrictive material, it can still be monitored, for example by placing a ring of a magnetostrictive material on the contour of this duct. The monitoring of the pressure in the duct is then coupled to the monitoring of the stress applied to the magnetostrictive material ring, by the method of FIG. 4.

FIG. 5 is a flowchart illustrating an example of implementation of the method of FIG. 4.

Curve 60 of FIG. 5 shows absolute value |B| of the maynetic field in the vicinity of the part to be monitored, along time. At an initial time t=0, the part for which the stress is desired to be monitored is used after having been prestressed to σₘₐₓ₂. During this use, the stress applied to the part varies but remains smaller than value |Bₘₐₓ₂| associated with initial stress σₘₐₓ₂ not to be exceeded.

At a time t_{STOP}, current stress |σ| strongly increases and exceeds stress |σₘₐₓ₂|. The measured field thus abruptly increases, and it is proceeded, in the flowchart of FIG. 4, to step 56 and an alert is transmitted. In the case of a duct where the pressure is monitored, this may for example generate a stopping of the flow in the duct to enable to replace said duct.

To measure the magnetic field in the vicinity of the part, any known maynetic field measurement device may be used, and especially a three-axis magnetometer, which may easily be positioned in the vicinity of the part.

The inventors also provide a variation of the method of FIG. 3 enabling to control the quality of parts at the factory gate. To achieve this, a tolerated stress σₜₒₗ is determined at the factory gate. Once the part has been manufactured, the curve of the magnetic field in the vicinity of the part is plotted for a stress varying between 0 and σₜₒₗ.If the curve is a straight line between 0 and σₜₒₗ, this means that the part has been submitted to a stress greater than σₜₒₗ. The part is then removed from the batch. If the curve is an exponential, the part is accepted. If the curve is a straight line followed by a significant slope change, the part is also accepted. One may also, in an alternative embodiment, provide rejecting a part having an exponential magnetic field curve, if there is a doubt on whether the magnetic memory of the part has been deleted, for example, by demagnetization (for example, if it is known that the part has necessarily been submitted at least to a low stress).

Another possible application of the phenomenon highlighted in relation with FIGS. 1 and 2A to 2C is a counting of the mechanical cycles to which a part is submitted, for example, to perform a study of the mechanical fatigue of the part. To achieve this, the part is initially pre-stressed and a magnetic field sensor is placed in the vicinity thereof.

Since the part has been pre-stressed to a high value, the magnetic field around it is substantially proportional to the stress applied to the part (on a curve such as the curve of FIG. 2E). Thus, by measuring the magnetic field, the stress applied to the part can be determined, and the mechanical cycles applied thereto can especially be counted (increase of the stress, followed by a decrease thereof) by for example detecting the variations of the field around a predetermined value.

Another possible application of the phenomenon highlighted in relation with FIGS. 1 and 2A to 2C is the forming of a remote gauge of the stress applied to a part. In this case, the part is highly pre-stressed and a magnetic field sensor is placed in the vicinity thereof. Since this corresponds to a region where the curve of the magnetic field according to the stress applied to the part could be established by a previous characterization step (bijective curve), a variation of the magnetic field can be correlated to a variation of the stress applied to the part.

Preferably, for a better readability in the case of these last two applications, the initial pre-stress will be applied under a magnetic field different from the field in which the part is used during the counting of mechanical cycles or during the real time measurement of the stress.

This may be used to know the wearing of a part after a number of mechanical cycles, be it for the study of the part or to detect a replacing thereof.

The inventors have noted that if a part has been submitted in the past to a stress taking the magnetization of the part to its anhysteretic curve, a curve of the magnetic field according to an increasing stress plotted afterwards may lack readability. In this specific case, this problem is solved by measuring the curve of the magnetic field versus the stress applied under an external field very different from the field under which the stress has been applied. Such a measurement may easily be performed by bringing properly-biased coils powered by a portable generator close to the part. Curves such as the curves of FIGS. 2A to 2C are then obtained.

It should be noted that the initial magnetic processing steps aiming at deleting the magnetic memory of the part may also be polarization steps, that is, cycling steps in a magnetic field with an alternated polarization, which may be decreasing and under a non-zero field.

Further, many other applications may result from the relation highlighted by the inventors between the magnetic field in the vicinity of a part made of a magnetostrictive material and a stress applied to this part. In particular, in civil works, the use of this method would enable to identify and to quantify an abnormally high stress area by the measurement of the magnetic field induced by the magnetic structure of the iron bars used for reinforced concrete in the structures of buildings, for example, in posts. It may also be provided to monitor, for example, the behavior of magnetic parts such as plates or threaded rods. It may for example be provided to monitor the behavior of a landing gear after a difficult landing (space and aeronautics).
CLAIMS

1. A method comprising the steps of:
(a) applying a variable mechanical stress to a part;
(b) measuring the magnetic field (B) in the vicinity of the part during the application of the variable mechanical stress to the part; and
(c) comparing said measurement with a reference measurement for detecting, in real time or ex post facto, whether the mechanical stress to which a part of a magnetic material having a detectable magnetostriction is subjected exceeds a mechanical stress level.

2. The method of claim 1, wherein the step (b) further comprises measuring the curve of the magnetic field (B) in the vicinity of the part according to an increasing stress (σ) which is applied thereto, up to said mechanical stress level (σₘₐₓ₁).

3. The method of claim 2, wherein step (c) is a step of determination of the shape of said curve by comparing it with reference curves.

4. The method of claim 3, wherein the reference curves are exponential or linear curves.

5. The method of claim 3, wherein the part of a magnetic material is deemed to have been stressed, in the past, with a maximum stress greater than said mechanical stress level (σₘₐₓ₁) if said measured curve becomes close to a linear curve, is deemed not to have been stressed or to have had its magnetic past deleted by a magnetic processing if said measured curve becomes dose to an exponential curve, and is deemed to have been stressed, in the past, with a maximum stress smaller than said mechanical stress level if the measured curve becomes close to a straight line, and then has a stronger slope to join an exponential curve.

6. The method of claim 5, wherein the value of the maximum stress to which the part has been subjected in the past corresponds to the stress value relative to the abrupt change of slope of said measured curve.

7. The method of claim 2, wherein the measurement of step (b) is performed under an external field different from the field under which the part has been stressed in the past.

8. The method of claim 1, further comprising an initial step comprising applying said mechanical stress level to the part.

9. The method of claim 6, wherein the comparison at step (c) further comprises determining whether the absolute value of the magnetic field in the vicinity of the part (|B|) measured at step (b) exceeds a magnetic field level (|Bₘₐₓ₂|) associated with said mechanical stress level.

10. The method of claim 8, further comprising a step of transmission of an alert if the absolute value of the magnetic field in the vicinity of the part (|B|) measured at step (b) exceeds said magnetic field level (|Bₘₐₓ₂|).

11. The method of claim 1, wherein the measurement of the magnetic field in the vicinity of the part is obtained by means of a three-axis magnetometer.

12. (canceled)

13. (canceled)

14. The method of claim 1, further comprising a preliminary step of magnetic processing of the part, by means of a demagnetization or a polarization, to delete stress to which the part has been previously subjected to from the magnetic memory.
